(19) United States
(12) Patent Application Publication
(10) Pub. No.: US 2008/0129455 A1
(43) Pub. Date: Jun. 5, 2008

(54) METHOD FOR FORMING RFID TAGS

(75) Inventor: Robert R. Oberle, Macungie, PA (US)

Correspondence Address: FLIESLER MEYER LLP, 650 CALIFORNIA STREET, 14TH FLOOR, SAN FRANCISCO, CA, 94108, US

(73) Assignee: RCD TECHNOLOGY INC., Quakertown, PA (US)

(21) Appl. No.: 11/752,166

(22) Filed: May 22, 2007

Related U.S. Application Data
(60) Provisional application No. 60/803,070, filed on May 24, 2006.

(51) Int. Cl. H04B 7/00; H01L 21/58

(52) U.S. Cl. 340/10.1; 438/118; 257/E21.505

(57) ABSTRACT

A method of constructing an RFID unit can include using a protective layer to hold an integrated circuit chip module to a substrate layer with an antenna unit while a conductive adhesive has not yet fully set.

### CLAIM OF PRIORITY

This application claims priority from the following co-pending applications, which are hereby incorporated in their entirety:

U.S. Provisional Application No. 60/803,070 entitled “METHOD FOR FORMING RFID TAGS”, by Robert R. Oberle, filed May 24, 2006 (Attorney Docket No. RCDT-01010US0).

### BACKGROUND OF INVENTION

Radio Frequency Identification (RFID) tags are typically small objects that can be attached to or incorporated into a product. RFID tags contain antenna to enable them to receive and respond to radio-frequency queries from an RFID tranciever. The RFID tags are used in a host of industries for purposes such as inventory control, security, personal identification and the like.

The RFID tags can be passive or active. Active devices have their own power supply. Passive devices rely on energization from the RFID tranciever. Passive and active RFID tags can use integrated circuit chips to modulate the identification response.

The construction of RFID units can consist of the attachment of a chip module to a substrate with an antenna unit. The chip module is typically attached to the substrate with an electrically conductive adhesive and then the combined unit can be further processed after the adhesive sets.

FIG. 5 shows a prior art strap system with an integrated circuit (IC) 502 attached to a strap substrate 504 which are then attached to a tag substrate 500. Such a system is shown in U.S. Pat. No. 6,951,156. The strap can be an interposer which affects the electrical interconnection between an IC 502 and the antenna. The strap can be made of a polymeric material with a conductive trace deposited therein. The conductive trace can be made with either a conductive silver ink or an etched or vapor deposited metal trace. In either case, there is no electrically conductive path through the bulk of the material from the one face to the other.

The strap containing the integrated circuit can be assembled onto the antenna with the IC 502 facing the substrate 506 on which the antenna is deposited. The mechanical structure of the strap is such that the substrate is bent around the IC 502 and puts the electrical bond points 508 (from strap to antenna) and 510 (from strap to IC) in a position of mechanical stress should the overall structure be subjected to bending or compressive forces. This mechanical stress can cause the interconnections between the strap and the IC 502 or strap and antenna to fail. Moreover, this configuration requires that the strap be held under constant pressure during the bond process to maintain the integrity of the bond.

Another prior art system is to punch a hole in the antenna substrate into which the IC fits. This allows the strap to lay flat (relative to the antenna substrate) during the assemble process and in use. The drawback of this process is that an additional layer of material must be placed over the back side of the antenna substrate to protect the IC.

Another prior art configuration has been demonstrated by Alien Technology wherein the chip resides in a recess in the strap substrate. This also allows the strap to lie flat relative to the antenna substrate but has the disadvantage of requiring a much thicker strap substrate and the use of a more complicated assembly process to produce the strap.

### BRIEF DESCRIPTION OF THE DRAWINGS

FIG. 1 is a cross sectional view of a RFID unit of one embodiment.

FIG. 2 is a top view of a RFID unit of one embodiment.

FIG. 3 is a diagram of an apparatus to construct a RFID unit of one embodiment.

FIGS. 4A-4C shows an example of a system using liners.

FIG. 5 shows prior art system.

FIGS. 6A-6B shows a system of one embodiment of the present invention.

FIGS. 7A-7D shows an exemplary construction method wherein the bond pads are placed on the substrate with predrilled holes.

FIGS. 8A-8D shows embodiments of the present invention.

### DETAILED DESCRIPTION

One embodiment of the present invention is a RFID tag including a tag substrate 602 with an antenna 604 and a strap substrate 606 with an IC 608, the strap substrate 606 positioned on the tags substrate, the IC 608 being electrically connected to the antenna 604 on the tag substrate 602 through a hole 610 and 612 in the strap substrate.

The hole 610 and 612 can be filed with a conductive material, such as a conductive adhesive. The conductive adhesive can be positioned on a bond pad of the tag substrate before the strap substrate is attached to the tag substrate. The conductive adhesive can alternately be placed in the hole after the strap substrate is attached to the substrate.

A strap can be produced with a small hole in the strap substrate in the region of the strap to antenna bond area 605. The strap can be assembled onto the antenna substrate with the chip facing up and away from the antenna substrate. This management means that the connections at bond area 605 and at electrical bond point 607 are not under stress.

The conductive adhesive applied to the bond pads of the antenna can be drawn up into the hole in the strap substrate by capillary action and the mechanical compression of the assembly process, thus forming the electrical connection between the strap and the antenna.

An alternate configuration is to produce tape or web with holes pre-formed in the substrate and deposit the conductive material for the strap in registry with the holes such that some of the conductive material coat the side of the hole. The IC can be subsequently assembled on the strap in the usual fashion and the strap assembled on the antenna substrate. This configuration may require less conductive material to be applied in the assemble process.

The tag substrate can be attached to the strap substrate using an adhesive. The IC need not contact the tag substrate. The strap substrate lies flat on the tag substrate. The antenna can be a coil or non coil antenna.

One embodiment of the present invention is a method to form an RFID tag. The method includes attaching a strap substrate with an IC to a tag substrate such that a hole in the strap substrate aligns with a bond pad on the tag substrate and electrically connecting the IC with an antenna on the tag substrate through the hole in the strap substrate.

One embodiment of the present invention is a RFID tag comprising a strap substrate having a first side with an IC attached and a hole; and a tag substrate attached to a second side of the strap substrate, the tag substrate having an antenna that is electrically connected to the IC through the hole.

One embodiment of the present invention comprises a method of constructing an RFID unit. The method comprises attaching an integrated circuit chip to a substrate with an antenna unit using an adhesive; and laminating a protective layer over at least a portion of the integrated circuit chip while the adhesive has not yet fully set.

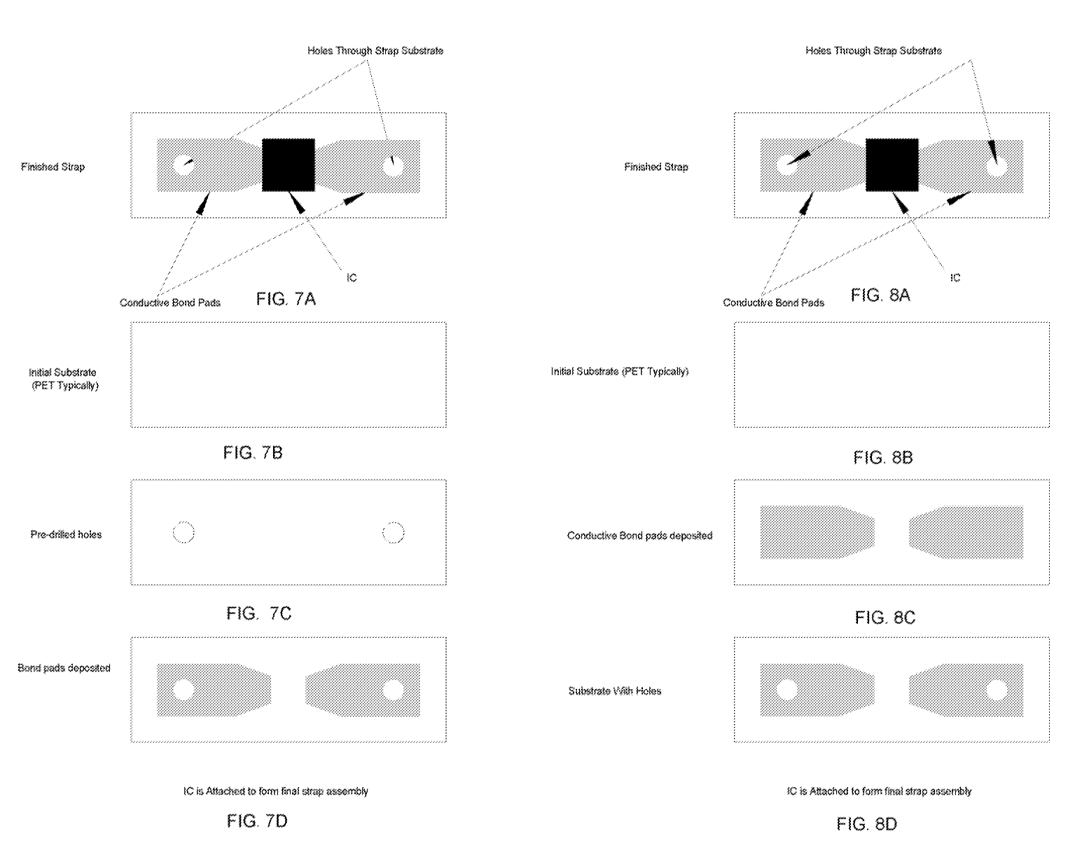

FIGS. 7A-7D shows an exemplary construction method wherein the bond pads are placed on the substrate with predrilled holes.

FIGS. 8A-8D shows an embodiment wherein bond pads are placed on a substrate first and the holes drilled later.

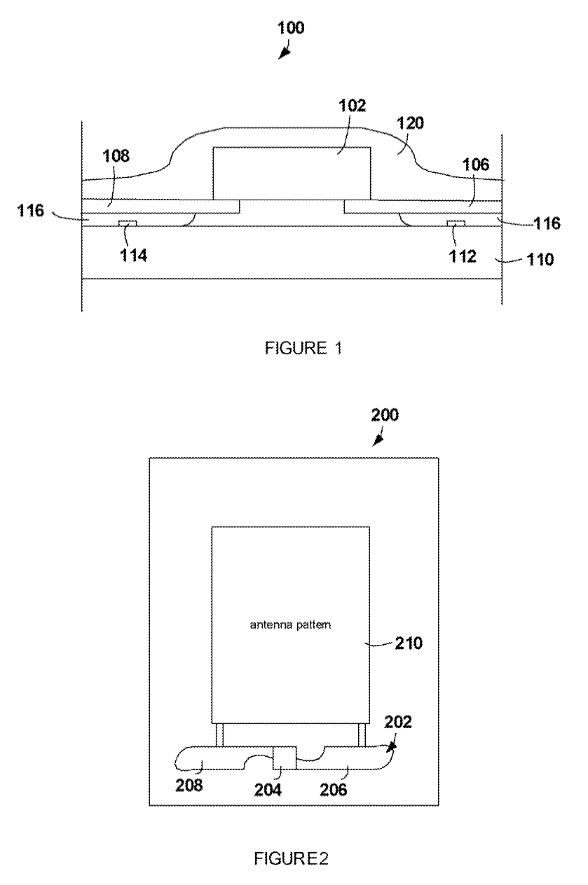

FIG. 1 illustrates a cross section diagram of an RFID unit 100 of one embodiment. In this embodiment, the integrated circuit 102 is part of a module 104 which also includes lead frame elements 106 and 108. Other connection elements other than a lead frame could be used in the module 104. The module 104 is adhesively connected to substrate 110 including antenna elements 112 and 114 using a conductive adhesive 116. The conductive adhesive 116 can be a conventional isotropic conductive adhesive, and anisotropic conductive adhesive or even solder such as solder paste.

FIG. 2 illustrates a top view where module 202 with IC 204 and lead frame 206 and 208 are connected using the conductive adhesive to the antenna unit 210 to form the RFID unit 200.

Looking again at FIG. 1, the protective layer 120 can be laminated over the module 104 including the integrated circuit 102. The protective layer 120 can hold the module 102 in place while the conductive adhesive 116 sets.

The laminating protective layer can be made of many types of materials including thermoplastic material, thermoset material, polyester, polystyrene, polypropylene, polyethylene. The protective layer may have an adhesive layer. In one embodiment, the protective layer is relatively stretchy and will conform the shape of the module or integrated circuit chip. In one embodiment, since the lamination is done before the adhesive is fully set, there does not have to be any dwell time between attaching and laminating steps. In one embodiment, the dwell time can be reduced below a minute. The attachment step can be done at a high rate due to the lack of requirement for the conductive adhesive to fully set. In one embodiment, the attachment is done at a rate of one attachment per second or greater. The conductive adhesive can be of such that it takes a long time to fully set since the protective layer holds the module in place. Thus, the conductive adhesive can take over a day to fully set, which can greatly increase the pot time of the adhesive in the apparatus to produce the RFID units. In one embodiment, the conductive adhesive can take over an hour to fully set.

The protective layer can have a radiation or heat curable adhesive. In one embodiment, the protective layer has an ultra violet (UV) curable adhesive that can be cured in a later step.

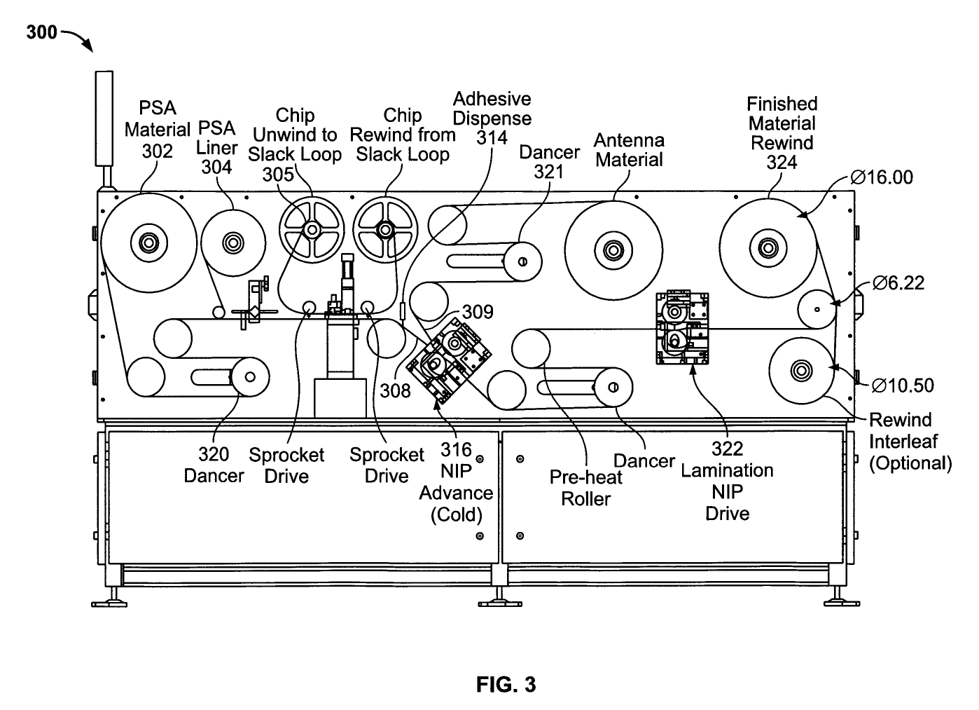

FIG. 3 illustrates an apparatus of one embodiment. In this embodiment, the laminating protective layer is held in a strip on roll 302. If the protective layer has a liner it can be removed onto roll 304. A roll 305 containing a strip with chip modules can feed to device 307 which can attached the chip module up side down on the protective layer 308. The antenna material can be a strip on roll 310. The conductive adhesive can be provided by an adhesive dispenser 314 to dispense upon module, such as on the leadframe of the module. An attachment unit 316 attaches the protective layer 308 with modules to the antenna material strip 309. Dancers 320 and 321 can be used to register the substrate strip having antenna units with the modules on the protective layer 308. A lamination unit 322 can later be used to laminate the protective layer over the integrated circuit chip module. The finished material can be rolled up into a roll 324 which can be held for later processing. The later processing can include cure step which can be done at a separate location from the apparatus 300. The laminating unit 322 can use hot rollers. The attaching unit 316 can operate at a rate greater than one attachment per second or greater.

In the example of FIG. 3, the integrated circuit chip (as part of the chip module) is attached to the protective layer before the attaching unit. This need not be the case, but it can allow the chips to be spaced on a strip such that the chips will register in position with the substrate strip having the antenna unit. In an alternate embodiment, the integrated circuit chip, as part of the chip module, is attached to the substrate with antenna first followed by the lamination of the protective layer.

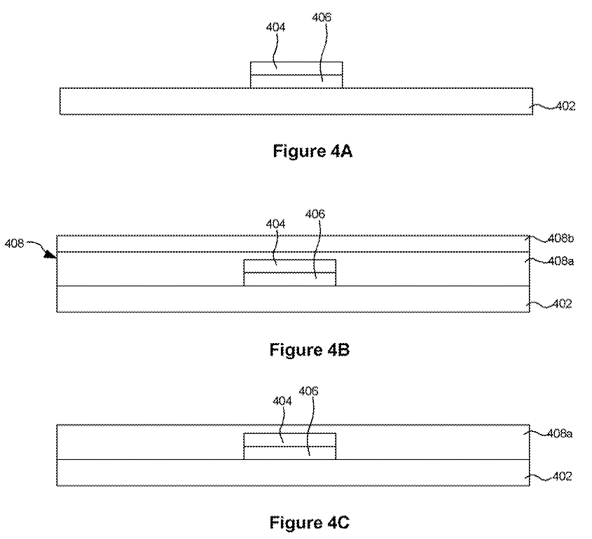

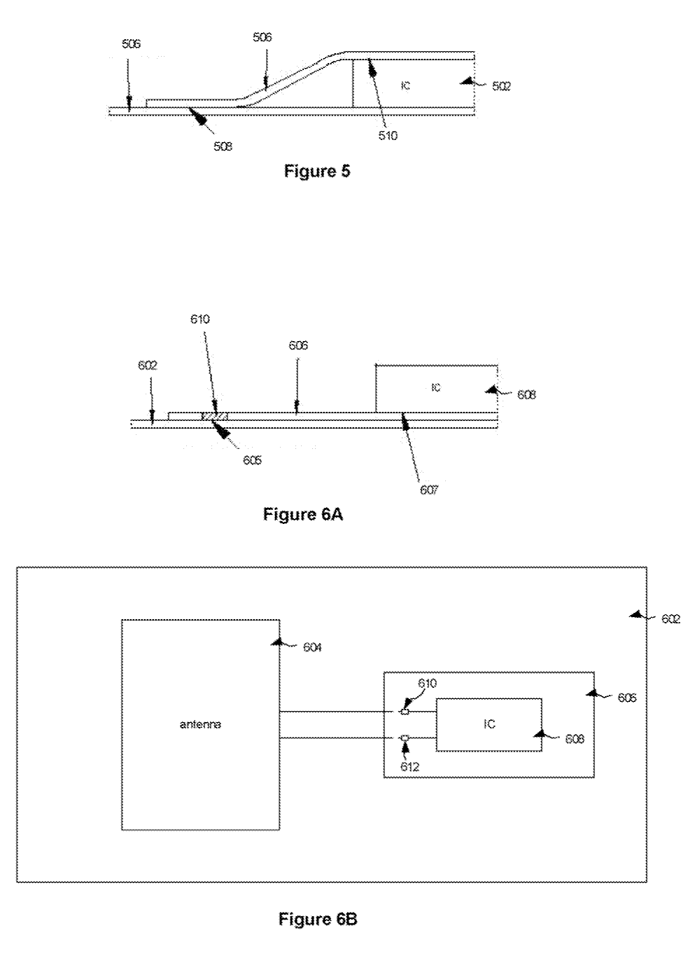

FIG. 4 shows an example of a system using liners. In FIG. 4A, an integrated circuit chip 404 is attached to a substrate 402 using adhesive 406 as shown in FIG. 4B. A protective layer 408 can be laminated over the integrated circuit chip 404 before the adhesive 406 sets. The protective layer can include a liner 408b and second adhesive 408a. The second adhesive 408a can be a thermaset, hot melt, heat activated, pressure sensitive, or other type of adhesive. The liner 408b can be removed as shown in FIG. 4C.

The protective layer can also be an uncured two-part adhesive, such as an epoxy like polyurethane. The two-part adhesive can be attached to the liner then placed over the substrate with attached IC. The two-part adhesive can then be cured to form an encapsulated RFID device, such as a credit or identification card.

The protective layer adhesive can be used to attach the unit to another element, such as a box or product for RFID tracking. In one embodiment, the unit acts as a label that can be attached to the element. There can be printed indicia, such as for the label, on one side of the substrate.

One embodiment of the present invention is a method of constructing an RFID unit comprising using a conductive adhesive to attach an integrated circuit chip module to a substrate with an antenna unit; and laminating a protective layer over at least a part of the integrated circuit chip module while the conductive adhesive has not yet fully set.

One embodiment of the present invention is a method of constructing an RFID unit comprising placing a integrated circuit chip module on a protective layer, wherein the protective layer includes an adhesive to hold the integrated circuit module; placing a conductive adhesive on at least portions of the integrated circuit chip module; and attaching the integrated circuit chip module to a substrate with an antenna unit.

One embodiment of the present invention is an RFID unit comprising a substrate with an antenna unit; an integrated circuit chip to the substrate with an antenna unit using an adhesive; and a protective layer laminated over at least a part of the integrated circuit chip while the adhesive has not yet fully set.

The chip module can be a single chip attached to a lead frame or suitable substrate with appropriate electrical connections for attachment to the antenna—examples of chip modules are offered by Philips Electronics, Netherlands (FCP package) and Alien Technologies of Morgan Hill CA (Alien Strap) The lead frame can terminates in two pads, which are intended to attach to the RFID circuit by a conductive adhesive. Chip modules can be utilized in order to alleviate the difficulties that normally arise when placing small integrated circuits (typical integrated circuits are <1 mm square, and the areal density of integrated circuits are typically very low, <0.25 units/square inch). In traditional application, the mounting of small integrated circuits without a leadframe leads to low process throughput owing to the time delay inherent in locating and placing such a small integrated circuit.

The disadvantages of previous processes relate to process throughput and reliability. Application of non-conductive epoxy under the integrated circuit and conductive epoxy to the outer leads results in a mechanically and electrically reliable assembly, however the dwell time for the circuit, i.e. that time that the circuit must be immobilized while the adhesives cure is typically several minutes. This may be decreased by using faster curing epoxy resins however the inherent chemical instability of so-called snap cure resins makes handling difficult and leads to excessive yield loss or high material wastage. Anisotropic adhesives, either tapes or pastes offer increased throughput with respect to epoxy adhesives however the dwell time per attachment is typically several seconds and during the dwell time the module must be held immobile on the substrate using considerable pressure to effect a reliable electrical connection. The use of a laminated protective layer can produce a throughput in excess of one attachment per second that insures mechanical stability of the device. The equipment can be relatively simple to maintain a very low cost of ownership of the overall process. This can be as low as $0.01 or less per attachment when considering the overall cost of materials and equipment amortization.

In one embodiment, a traditional conductive adhesive can be placed over the terminals of the circuit to which the module is to be attached or placed on the terminals of the module prior to assembly.

The module can be placed on the substrate with contact of the terminals of the module on the appropriate terminal of the circuit. Alternatively, the module may be temporarily attached to a tape which is subsequently laminated to the circuit.

A protective layer can be laminated over the module of a tape which holds the module in place while the adhesive is cured (partially or fully). The tape may held in place by a variety of adhesives including an adhesive selected from any of a number of adhesive types; hot melt, pressure sensitive, UV cure, thermoset etc. This laminate may cover the module fully or partially or it may be advantageous to use a segmented or multiple adhesives for specific uses.

A curing step can be done to set, such as cure, the conductive adhesive. This step may be of a type that initiates cure of the adhesive which proceeds after the circuit has been removed from the immediate vicinity of the attachment and/or curing station.

The protective layer can form a protective cover for the module, particularly if the laminate conforms closely to the shape of the module after lamination. There is no requirement for dwell time in the placement equipment. This means that parts with a partially cured adhesive can be safely rolled up and stored while the curing process takes place. This has the dual benefit of increasing process throughput and reducing material waste costs. Tape lamination equipment presently available can be modified to suit this application. The throughput of exiting equipment is sufficient to meet the imperative of a low cost high throughput process for placement and attachment of the module.

In alternate embodiments, a curable adhesive can be placed over the module contemporaneously with the conductive adhesive; an anisotropic adhesive can be used rather than traditional conductive adhesive; and/or an anisotropic adhesive can be used in place of both the traditional conductive adhesive and a laminating adhesive.

An alternate embodiment is a method for constructing a flexible circuit comprising attaching an integrated circuit chip to a substrate with an circuit traces using an adhesive; and laminating a protective layer over at least part of the integrated circuit chip while the adhesive has not yet fully set.

The foregoing description of preferred embodiments of the present invention has been provided for the purposes of illustration and description. It is not intended to be exhaustive or to limit the invention to the precise forms disclosed. Many embodiments were chosen and described in order to best explain the principles of the invention and its practical application, thereby enabling others skilled in the art to understand the invention for various embodiments and with various modifications that are suited to the particular use contemplated. It is intended that the scope of the invention be defined by the claims and their equivalents.

What is claimed is:

1. A RFID tag including:
a tag substrate with an antenna; and
a strap substrate with an IC, the strap substrate positioned on the tab substrate, the IC being electrically connected to the antenna on the tag substrate through a hole in the strap substrate.

2. The RFID tag of claim 1, wherein the hole is filed with a conductive material.

3. The RFID tag of claim 2, wherein the hole is filled with a conductive adhesive.

4. The RFID tag of claim 3, wherein the conductive adhesive is positioned on a bond pad of the tag substrate before the strap substrate is attached to the tag substrate.

5. The RFID tag of claims 4, wherein the conductive adhesive is placed in the hole after the strap substrate is attached to the substrate.

6. The RFID tag of claim 1, wherein the tag substrate is attached to the strap substrate using an adhesive.

7. The RFID tag of claim 1, wherein the IC does not contact the tag substrate.

8. The RFID tag of claim 1, wherein the strap substrate lies flat on the tag substrate.

9. The RFID tag of claim 1, wherein the antenna is a coil antenna.

10. The RFID tag of claim 1, wherein the antenna is a non-coil antenna.

11. The method to form an RFID tag comprising:
attaching a strap substrate with an IC to a tag substrate such that a hole in the strap substrate aligns with a bond pad on the tag substrate; and
electrically connecting the IC with an antenna on the tag substrate through the hole in the strap substrate.

12. The method of claim 11, wherein the hole is filed with a conductive material.

13. The method of claim 12, wherein the hole is filled with a conductive adhesive.

14. The method of claim 13, wherein the conductive adhesive is positioned on a bond pad of the tag substrate before the strap substrate is attached to the tag substrate.

15. The method of claims 14, wherein the conductive adhesive is placed in the hole after the strap substrate is attached to the substrate.

16. The method of claim 11, wherein the tag substrate is attached to the strap substrate using an adhesive.

17. The method of claim 11, wherein the IC does not contact the tag substrate.

18. The method of claim 11, wherein the strap substrate lies flat on the tag substrate.

19. The method of claim 11, wherein the antenna is a coil antenna.

20. The method of claim 11, wherein the antenna is a non-coil antenna.

21. An RFID tag comprising:
a strap substrate having a first side with an IC attached and a hole; and
a tag substrate attached to a second side of the strap substrate, the tag substrate having an antenna that is electrically connected to the IC through the hole.
